(19) United States
(12) Patent Application Publication
(10) Pub. No.: US 2026/0332110 A1
(43) Pub. Date: Oct. 22, 2026

(54) RADIO-FREQUENCY MODULE

(71) Applicant: Murata Manufacturing Co., Ltd., Nagaokakyo-shi (JP)

(72) Inventors: Kazuhiro TAKAHASHI, Nagaokakyo-shi (JP); Kensuke TAKIMOTO, Nagaokakyo-shi (JP); Shogo YANASE, Nagaokakyo-shi (JP)

(73) Assignee: Murata Manufacturing Co., Ltd., Nagaokakyo-shi (JP)

(21) Appl. No.: 19/648,016

(22) Filed: Apr. 15, 2026

(30) Foreign Application Priority Data
Apr. 22, 2025 (JP) 2025-070842

(51) Int. Cl. H03F 3/24; H01P 5/12; H04B 1/00

(52) U.S. Cl. CPC H03F 3/245; H01P 5/12; H04B 1/0053; H03F 2200/451

(57) ABSTRACT

A radio-frequency module has a semiconductor integrated component including first and second power amplifiers, a splitter including an input terminal, a first output terminal connected to an input end of the power amplifier, and a second output terminal connected to an input end of the power amplifier, and a combiner including a first input terminal connected to an output end of the power amplifier, a second input terminal connected to an output end of the power amplifier, and an output terminal. The first and second power amplifiers are disposed along a first side of the semiconductor integrated component inside the semiconductor integrated component. The splitter is disposed along a third side of the semiconductor integrated component in plan view of a module laminate. The combiner is disposed along the first side of the semiconductor integrated in plan view of the module laminate.

### CROSS-REFERENCE TO RELATED APPLICATION

This application claims priority under 35 U.S.C. § 119 to Japanese Patent Application No. 2025-070842, filed on Apr. 22, 2025, in the Japanese Patent Office. The entire contents of the above-identified application are incorporated herein by reference for all purposes as if fully set forth herein.

### BACKGROUND

### 1. Field

The present disclosure relates to a radio-frequency module.

### 2. Description of the Related Art

International Publication No. WO2024/247431 discloses a radio-frequency module having two amplifiers (power amplifiers), a combiner circuit (a combiner) configured to combine outputs from the two amplifiers, and a divider circuit (a splitter) configured to split a radio-frequency signal into two radio-frequency signals and output them to the respective two amplifiers. In the radio-frequency module in International Publication No. WO2024/247431, the divider circuit, the power amplifiers, and the combiner circuit are arranged side by side in one line.

### SUMMARY

A radio-frequency module according to an aspect of the present disclosure includes: a module laminate; a first semiconductor integrated component disposed at the module laminate and including a first power amplifier and a second power amplifier; a first splitter disposed at the module laminate and including a first input terminal, a first output terminal connected to an input end of the first power amplifier, and a second output terminal connected to an input end of the second power amplifier; and a first combiner disposed at the module laminate and including a second input terminal connected to an output end of the first power amplifier, a third input terminal connected to an output end of the second power amplifier, and a third output terminal. The first splitter and the first combiner are each a transformer or a quadrature hybrid circuit. In plan view of the module laminate, the first semiconductor integrated component has a first side and a second side facing each other and a third side and a fourth side adjacent to the first side and the second side and facing each other. The first power amplifier and the second power amplifier are disposed along the first side inside the first semiconductor integrated component. The first splitter is disposed along the third side outside the first semiconductor integrated component in plan view of the module laminate. The first combiner is disposed along the first side outside the first semiconductor integrated component in plan view of the module laminate.

### BRIEF DESCRIPTION OF THE DRAWINGS

FIG. 1 is a configuration diagram of a communication device according to Embodiment 1;

FIG. 2 is a circuit configuration diagram of a radio-frequency module according to Embodiment 1;

FIG. 3 is a plan view of the radio-frequency module according to Embodiment 1;

FIG. 4 is a plan view of the radio-frequency module according to Embodiment 1;

FIG. 5 is a sectional view of the radio-frequency module according to Embodiment 1;

FIG. 6 is a layout diagram of a semiconductor integrated component, splitters, and combiners according to Embodiment 1;

FIG. 7 is a plan view of a radio-frequency module according to a modification of Embodiment 1;

FIG. 8 is a plan view of the radio-frequency module according to the modification of Embodiment 1;

FIG. 9 is a sectional view of the radio-frequency module according to the modification of Embodiment 1;

FIG. 10 is a partial plan view of a radio-frequency module according to Embodiment 2;

FIG. 11 is a partial sectional view of the radio-frequency module according to Embodiment 2;

FIG. 12 is a partial plan view of a radio-frequency module according to Embodiment 3; and

FIG. 13 is a partial plan view of a radio-frequency module according to Embodiment 4.

### DETAILED DESCRIPTION

The inventors have recognized that, with the configuration of the related art, the length of interconnection from the splitter to the combiner with the two power amplifiers in between is long, which may degrade the characteristics of the radio-frequency module.

Thus, the disclosure is directed to providing a radio-frequency module improved in characteristics by reducing an increase in the length of interconnection from the splitter to the combiner with the two power amplifiers in between.

Embodiments are described in detail below using the drawings. Note that the embodiments described below each show a comprehensive or specific example. Numeric values, shapes, materials, constituents, how the constituents are arranged and connected, and the like given in the embodiments below are merely examples, and there is no intention of limiting the present disclosure to them.

Note that the drawings are schematic diagrams where emphasis, omission, or ratio adjustment are made as needed to illustrate embodiments. The drawings are therefore not necessarily depicted precisely and may show shapes, positional relations, and ratios that differ from the actual ones. Configurations that are substantially the same are denoted by the same reference numeral throughout the drawings, and descriptions may be omitted or simplified to avoid repetition.

Throughout the drawings to be referred to below, the x-axis and the y-axis are axes orthogonal to each other on a plane parallel to the main surfaces of a module laminate, and the z-axis is an axis perpendicular to the main surfaces of the module laminate, with its positive direction representing an upward direction and its negative direction representing a downward direction.

In descriptions below, “connected” includes not only being connected by a connection terminal and/or an interconnection conductor, but also being connected electrically through a different circuit element. What is meant by “A is connected to B in a switchable manner” is that connection and disconnection between A and B are switchable and that A is connected to B via a switch. Note that “A is connected to B” includes “A is connected to B in a switchable manner”.

What is meant by “C is connected between A and B” is that C is connected at one end to A and at the other end to B and that C is connected in series to a path connecting A and B. What is meant by “C is connected between the ground and a path connecting A and B” is that C is connected at one end to the path connecting A and B and at the other end to the ground and that C is shunt-connected to the path connecting A and B. What is meant by “a path connecting A and B” is a path formed of a conductor that electrically connects A and B.

A “pass band of a filter” is a portion of the frequency spectrum transmitted by the filter and is defined as a frequency band between two frequencies that are 3 dB greater than the minimum power insertion loss.

A “transmission band” means a frequency band used for transmission by the communication device, and a “reception band” means a frequency band used for reception by the communication device. For example, in a case of the frequency division duplex (FUDD) band, frequency bands different from each other (an uplink band and a downlink band) are used as a transmission band and a reception band. Also, for example, in a case of the time division duplex (TDD) band, the same frequency band is used as a transmission band and a reception band.

“Terminal” means a point where a conductor within an element terminates. Note that when the impedance of a conductor between elements is sufficiently low, a terminal is interpreted not only as a single point, but also as a given point on the conductor between elements or as the entire conductor. “A component is disposed at a substrate” includes the component being disposed on a main surface of the substrate and the component being disposed in the substrate. “A component is disposed on a substrate” includes not only the component being disposed in contact with a main surface of the substrate, but also the component being disposed above the main surface without making contact therewith (for example, the component being stacked on another component disposed in contact with the main surface). Also, “a component is disposed on a main surface of a substrate” may include the component being disposed in a recessed portion formed at the main surface. “A component is disposed in a substrate” includes not only the component being encapsulated in the substrate, but also the component being entirely disposed between the main surfaces of the substrate but partly not covered by the substrate and only part of the component being disposed in the substrate.

What is meant by “A is disposed between B and C” is that at least one of a plurality of line segments connecting a given point on B and a given point on C passes through A. What is meant by “A is disposed closer to C than B is” is that the distance between A and C is shorter than the distance between B and C. Conversely, what is meant by “A is disposed farther from C than B is” is that the distance between A and C is longer than the distance between B and C. What is meant by the “distance between A (B) and C” is the length of the shortest one of a plurality of line segments connecting a given point on the surface of A (B) and a given point on the surface of C (i.e., the shortest distance).

What is meant by “in plan view of a module laminate” is to see an object orthographically projected onto an xy-plane in the negative direction of the z-axis. What is meant by “A and B overlap in plan view of a module laminate” is that the region of A orthographically projected onto the xy-plane overlaps with the region of B orthographically projected onto the xy-plane.

What is meant by “A is disposed along a side of B in plan view of a module laminate” is that A and B are disposed such that one side of a rectangle surrounding A projected onto the xy-plane with the minimum area is parallel to one side of a rectangle surrounding B projected onto the xy-plane with the minimum area. “Parallel” herein includes not only being precisely parallel, but also being in a range where it is substantially regarded as parallel (an angle between two sides is greater than 0 degrees and smaller than 30 degrees).

“A is disposed adjacent to a side of B in plan view of a module laminate” represents that A and a side of B projected onto the xy-plane are closely disposed and specifically means that there is no other circuit component or no other side of B in the space between A and the side of B onto the xy-plane. In other words, what is meant by “A is disposed adjacent to a side of B in plan view of a module laminate” is that none of a plurality of line segments extending from a point on a border line of A facing the side of B to the side of B in a direction normal to the border line on the xy-plane passes through any of circuit components other than A or B or any of the rest of the sides of B. Thus, overlap of A with the side of B on the xy-plane is permissible. What is meant by a circuit component herein is a component including an active element and/or a passive element. Specifically, a circuit component includes an active component such as a transistor or a diode, and a passive component such as an inductor, a transformer, a capacitor, or a resistor, and does not include an electromechanical component such as a terminal, a connector, or an interconnection.

Also, terms representing a relation between elements, such as “parallel” and “perpendicular,” terms representing the shape of an element, such as “rectangular,” as well as ranges of numerical values do not represent precise meanings, and may include an error within a substantially equivalent range, for example, a few percent.

### Embodiment 1

Embodiment 1 is described below.

### [1.1. Configuration of Communication Device 5]

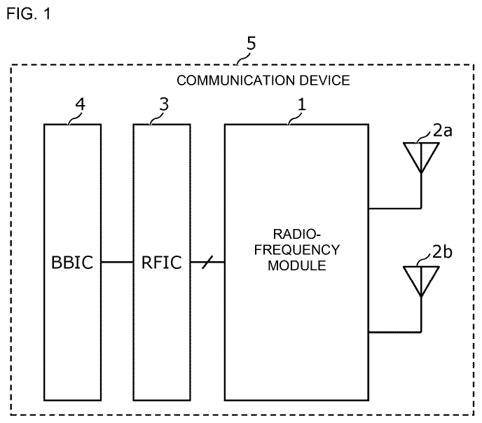

First, the configuration of a communication device 5 according to the present embodiment is described with reference to FIG. 1. FIG. 1 is a schematic diagram of the communication device 5 according to the present embodiment.

Note that FIG. 1 shows an example configuration, and the communication device 5 may be implemented using any of various circuit implementations and circuit technologies. Thus, the description of the communication device 5 provided below is not to be construed as limiting.

The communication device 5 can be used to provide wireless connection. For example, the communication device 5 can be implemented in a UE in a cellular network (also referred to as a mobile network), such as a mobile phone, a smartphone, a tablet computer, or a wearable device. In another example, the communication device 5 can be implemented to provide wireless connection to an Internet-of-Things (IoT) sensor device, a medical/healthcare device, a vehicle, an unmanned aerial vehicle (UAV) (what is called a drone), or an automated guided vehicle (AGV). In yet another example, the communication device 5 can be implemented to provide wireless connection for a wireless access point or a wireless hot spot.

The communication device 5 includes a radio-frequency module 1, antennas 2a and 2b, a radio-frequency integrated circuit (RFIC) 3, and a baseband integrated circuit (BBIC) 4.

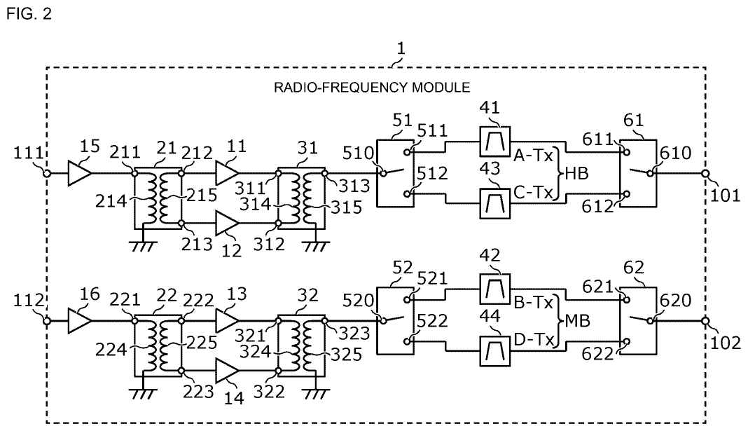

The radio-frequency module 1 can transmit radio-frequency signals between the RFIC 3 and the antennas 2a and 2b. The circuit configuration of the radio-frequency module 1 will be described later using FIG. 2.

The antennas 2a and 2b are connected to the radio-frequency module 1. The antennas 2a and 2b can accept a radio-frequency signal from the radio-frequency module 1 and transmit it to the outside of the communication device 5. Further, the antennas 2a and 2b may receive a radio-frequency signal from the outside of the communication device 5 and supply it to the radio-frequency module 1. One or both of the antennas 2a and 2b may external to the communication device 5. Also, the communication device 5 may include one or more antennas in addition to the antennas 2a and 2b.

The RFIC 3 is an example of a signal processing circuit that processes a radio-frequency signal. Specifically, the RFIC 3 can perform signal processing such as up-conversion on a transmission signal inputted from the BBIC 4 and output the radio-frequency transmission signal generated by the signal processing to the radio-frequency module 1. Further, the RFIC 3 may perform signal processing such as down-conversion on a radio-frequency reception signal inputted via the radio-frequency module 1 and output the reception signal generated by the signal processing to the BBIC 4. Also, the RFIC 3 may have a control unit that controls the switches, amplifiers, and the like in the radio-frequency module 1. Note that some or all of the functions of the RFIC 3 as the control unit may be included outside of the RFIC 3 and may be included in, for example, the BBIC 4 or the radio-frequency module 1.

The BBIC 4 is a baseband signal processing circuit that performs signal processing using a frequency band lower than the radio-frequency signals transmitted by the radio-frequency module 1. A signal processed by the BBIC 4 is, for example, an image signal for image display and/or an audio signal for speakerphone call.

### [1.2. Circuit Configuration of Radio-Frequency Module 1]

Next, the circuit configuration of the radio-frequency module 1 according to the present embodiment is described with reference to FIG. 2. FIG. 2 is a circuit configuration diagram of the radio-frequency module 1 according to the present embodiment.

Note that FIG. 2 shows an example circuit configuration, and the radio-frequency module 1 may be implemented using any of various circuit implementations and circuit technologies. Thus, the description of the radio-frequency module 1 provided below is not to be construed as limiting.

The radio-frequency module 1 includes power amplifiers 11, 12, 13, 14, 15 and 16, splitters 21 and 22, combiners 31 and 32, filters 41, 42, 43, and 44, switches 51, 52, 61, and 62, antenna connection terminals 101 and 102, and radio-frequency input terminals 111 and 112. The switches 51, 52, 61, and 62 may be controlled by processing circuitry (e.g., a logic controller or RFIC) configured to selectively route signals based on the active frequency band.

The antenna connection terminals 101 and 102 are external connection terminals of the radio-frequency module 1 and are terminals for supplying radio-frequency signals to the antennas 2a and 2b. The antenna connection terminal 101 is connected to the antenna 2a outside the radio-frequency module 1 and is connected to the switch 61 inside the radio-frequency module 1. The antenna connection terminal 102 is connected to the antenna 2b outside the radio-frequency module 1 and is connected to the switch 62 inside the radio-frequency module 1.

The radio-frequency input terminals 111 and 112 are external connection terminals of the radio-frequency module 1 and are terminals for receiving radio-frequency signals from the RFIC 3. The radio-frequency input terminals 111 and 112 are connected to the RFIC 3 outside the radio-frequency module 1 and connected, respectively, to the power amplifiers 15 and 16 inside the radio-frequency module 1.

The power amplifiers 11 and 12 are an example of the first power amplifier and an example of the second power amplifier, respectively, and are a pair of final-stage amplifiers (power stage amplifiers) connected in parallel. The power amplifiers 11 and 12 are connected between the splitter 21 and the combiner 31. Specifically, the input ends of the power amplifiers 11 and 12 are connected to the splitter 21, and the output ends of the power amplifiers 11 and 12 are connected to the combiner 31. The power amplifiers 11 and 12 are differential amplifiers and can amplify a balanced signal (i.e., a differential signal) using power supplied from a power source.

The power amplifiers 13 and 14 are an example of the third power amplifier and an example of the fourth power amplifier, respectively, and are a pair of final-stage amplifiers connected in parallel. The power amplifiers 13 and 14 are connected between the splitter 22 and the combiner 32. Specifically, the input ends of the power amplifiers 13 and 14 are connected to the splitter 22, and the output ends of the power amplifiers 13 and 14 are connected to the combiner 32. The power amplifiers 13 and 14 are differential amplifiers and can amplify a differential signal using power supplied from a power source.

The power amplifier 15 is an example of the fifth power amplifier and is a non-final-stage amplifier (also referred to as a driving-stage amplifier). The power amplifier 15 is connected between the radio-frequency input terminal 111 and the splitter 21. Specifically, the input end of the power amplifier 15 is connected to the radio-frequency input terminal 111, and the output end of the power amplifier 15 is connected to the splitter 21. The power amplifier 15 can amplify an unbalanced signal using power supplied from a power source.

The power amplifier 16 is an example of the sixth power amplifier and is a non-final-stage amplifier. The power amplifier 16 is connected between the radio-frequency input terminal 112 and the splitter 22. Specifically, the input end of the power amplifier 16 is connected to the radio-frequency input terminal 112, and the output end of the power amplifier 16 is connected to the splitter 22. The power amplifier 16 can amplify an unbalanced signal using power supplied from the power source.

The splitter 21 is an example of the first splitter and is connected between the power amplifier 15 and the power amplifiers 11 and 12. Specifically, the splitter 21 includes an input terminal 211 and output terminals 212 and 213. The input terminal 211 is an example of the first input terminal and is connected to the output end of the power amplifier 15. The output terminal 212 is an example of the first output terminal and is connected to the input end of the power amplifier 11. The output terminal 213 is an example of the second output terminal and is connected to the input end of the power amplifier 12. In the present embodiment, the splitter 21 is a transformer (i.e., what is called a balun) and includes a primary coil 214 and a secondary coil 215 that can couple with the primary coil 214. The respective ends of the primary coil 214 are connected to the input terminal 211 and the ground. The respective ends of the secondary coil 215 are connected to the output terminals 212 and 213. With such a connection configuration, the splitter 21 can convert a radio-frequency signal (an unbalanced signal) amplified by the power amplifier 15 into two radio-frequency signals (balanced signals) with a 180-degree phase difference and supply the two radio-frequency signals to the respective power amplifiers 11 and 12.

The splitter 22 is an example of the second splitter and is connected between the power amplifier 16 and the power amplifiers 13 and 14. Specifically, the splitter 22 includes an input terminal 221 and output terminals 222 and 223. The input terminal 221 is an example of the fourth input terminal and is connected to the output end of the power amplifier 16. The output terminal 222 is an example of the fourth output terminal and is connected to the input end of the power amplifier 13. The output terminal 223 is an example of the fifth output terminal and is connected to the input end of the power amplifier 14. In the present embodiment, the splitter 22 is a transformer (what is called a balun) and includes a primary coil 224 and a secondary coil 225 that can couple with the primary coil 224. The respective ends of the primary coil 224 are connected to the input terminal 221 and the ground. The respective ends of the secondary coil 225 are connected to the output terminals 222 and 223. With such a connection configuration, the splitter 22 can convert a radio-frequency signal (an unbalanced signal) amplified by the power amplifier 16 into two radio-frequency signals (balanced signals) with a 180-degree phase difference and supply the two radio-frequency signals to the respective power amplifiers 13 and 14.

The combiner 31 is an example of the first combiner and is connected between the power amplifiers 11 and 12 and the filters 41 and 43. Specifically, the combiner 31 includes input terminals 311 and 312 and an output terminal 313. The input terminal 311 is an example of the second input terminal and is connected to the output end of the power amplifier 11. The input terminal 312 is an example of the third input terminal and is connected to the output end of the power amplifier 12. The output terminal 313 is an example of the third output terminal and is connected to the filters 41 and 43 in a switchable manner through the switch 51. In the present embodiment, the combiner 31 is a transformer (what is called a balun) and includes a primary coil 314 and a secondary coil 315 that can couple with the primary coil 314. The respective ends of the primary coil 314 are connected to the input terminals 311 and 312. The respective ends of the secondary coil 315 are connected to the output terminal 313 and the ground. With such a connection configuration, the combiner 31 can convert the balanced signals amplified by the power amplifiers 11 and 12 into an unbalanced signal and supply the unbalanced signal to the switch 51.

The combiner 32 is an example of the second combiner and is connected between the power amplifiers 13 and 14 and the filters 42 and 44. Specifically, the combiner 32 includes input terminals 321 and 322 and an output terminal 323. The input terminal 321 is an example of the fifth input terminal and is connected to the output end of the power amplifier 13. The input terminal 322 is an example of the sixth input terminal and is connected to the output end of the power amplifier 14. The output terminal 323 is an example of the sixth output terminal and is connected to the filters 42 and 44 in a switchable manner through the switch 52. In the present embodiment, the combiner 32 is a transformer (what is called a balun) and includes a primary coil 324 and a secondary coil 325 that can couple with the primary coil 324. The respective ends of the primary coil 324 are connected to the input terminals 321 and 322. The respective ends of the secondary coil 325 are connected to the output terminal 323 and the ground. With such a connection configuration, the combiner 32 can convert the balanced signals amplified by the power amplifiers 13 and 14 into an unbalanced signal and supply the unbalanced signal to the switch 52.

Note that the splitter 21 and the combiner 31 may each be circuits other than a transformer, e.g., a quadrature hybrid circuit (i.e., a 90-degree hybrid coupler). In this case, the power amplifiers 11 and 12 are balanced amplifiers or Doherty amplifiers and can amplify two radio-frequency signals with a 90-degree phase difference. Also, for example, the splitter 22 and the combiner 32 may each be a quadrature hybrid circuit. In this case, the power amplifiers 13 and 14 are balanced amplifiers or Doherty amplifiers and can amplify two radio-frequency signals with a 90-degree phase difference.

The filter 41 is an example of the first filter and is a band pass filter having a pass band including a transmission band of Band A (A-Tx). The filter 41 is connected between the switches 51 and 61. Specifically, the filter 41 is connected at one end to the switch 51 and at the other end to the switch 61.

The filter 42 is an example of the second filter and is a band pass filter having a pass band including a transmission band of Band B (B-Tx). The filter 42 is connected between the switches 52 and 62. Specifically, the filter 42 is connected at one end to the switch 52 and at the other end to the switch 62.

The filter 43 is a band pass filter having a pass band including a transmission band of Band C (C-Tx). The filter 43 is connected between the switches 51 and 61. Specifically, the filter 43 is connected at one end to the switch 51 and at the other end to the switch 61.

The filter 44 is a band pass filter having a pass band including a transmission band of Band D (D-Tx). The filter 44 is connected between the switches 52 and 62. Specifically, the filter 44 is connected at one end to the switch 52 and at the other end to the switch 62.

Note that the filters 41 to 44 may be other than band pass filters. Some or all of the filters 41 to 44 may be a band elimination filter, a high pass filter, a low pass filter, or a combination of these.

Bands A to D are each a frequency band for a communication system built using a radio access technology (RAT). Bands A to D are defined in advance by, for example, a standardizing body (such as, for example, 3GPP (registered trademark) or Institute of Electrical and Electronics Engineers (IEEE)). Examples of the communication system include a 5th-Generation New Radio (5GNR) system, a 4th-Generation Long Term Evolution (4GLTE) system, and a 2nd-Generation Global System for Mobile Communications (2GGSM) system.

Band A is an example of the first band. Bands A and C are frequency bands included in a first band group (in the present embodiment, a high band group (HB: 2300 MHz to 2690 MHz)). Band B is an example of the second band. Bands B and D are frequency bands included in a second band group (in the present embodiment, a mid-band group (MB: 1427 MHz to 2200 MHz)). Note that the combination of the first band group and the second band group may be combinations other than the high-band group and the mid-band group. For example, the combination of the first band group and the second band group may be any two of a low band group (LB: 617 MHz to 960 MHz), the mid-band group, the high band group, and an ultra-high band group (UHB: 3300 MHz to 5000 MHz). Also, the first band group and the second band group may be other than a band group within Frequency Range 1 (FR1) (600 MHz to 7.125 GHz). The first band group and/or the second band group may be, for example, a band group within Frequency Range 2 (FR 2) (24.25 GHz to 71 GHz) or Frequency Range 3 (FR 3) (7.125 GHz to 24.25 GHz).

The switch 51 is an example of the first switch and is connected between the combiner 31 and the filters 41 and 43. Specifically, the switch 51 includes a common terminal 510 and selection terminals 511 and 512. The common terminal 510 is connected to the output terminal 313 of the combiner 31. The selection terminals 511 and 512 are connected to the filters 41 and 43, respectively. With such a connection configuration, the switch 51 can connect the common terminal 510 to the selection terminal 511 or 512 selectively based on, for example, a control signal from the RFIC 3. The switch 51 is configured by, for example, a single-pole double-throw (SPDT) switch circuit.

The switch 52 is an example of the second switch and is connected between the combiner 32 and the filters 42 and 44. Specifically, the switch 52 includes a common terminal 520 and selection terminals 521 and 522. The common terminal 520 is connected to the output terminal 323 of the combiner 32. The selection terminals 521 and 522 are connected to the filters 42 and 44, respectively. With such a connection configuration, the switch 52 can connect the common terminal 520 to the selection terminal 521 or 522 selectively based on, for example, a control signal from the RFIC 3. The switch 52 is configured by, for example, an SPDT switch circuit.

The switch 61 is connected between the antenna connection terminal 101 and the filters 41 and 43. Specifically, the switch 61 includes a common terminal 610 and selection terminals 611 and 612. The common terminal 610 is connected to the antenna connection terminal 101. The selection terminals 611 and 612 are connected to the filters 41 and 43, respectively. With such a connection configuration, the switch 61 can connect the common terminal 610 to the selection terminal 611 or 612 selectively based on, for example, a control signal from the RFIC 3. The switch 61 is configured by, for example, an SPDT switch circuit.

The switch 62 is connected between the antenna connection terminal 102 and the filters 42 and 44. Specifically, the switch 62 includes a common terminal 620 and selection terminals 621 and 622. The common terminal 620 is connected to the antenna connection terminal 102. The selection terminals 621 and 622 are connected to the filters 42 and 44, respectively. With such a connection configuration, the switch 62 can connect the common terminal 620 to the selection terminal 621 or 622 selectively based on, for example, a control signal from the RFIC 3. The switch 62 is configured by, for example, an SPDT switch circuit.

### [1.3. Implementation Example of Radio-Frequency Module 1]

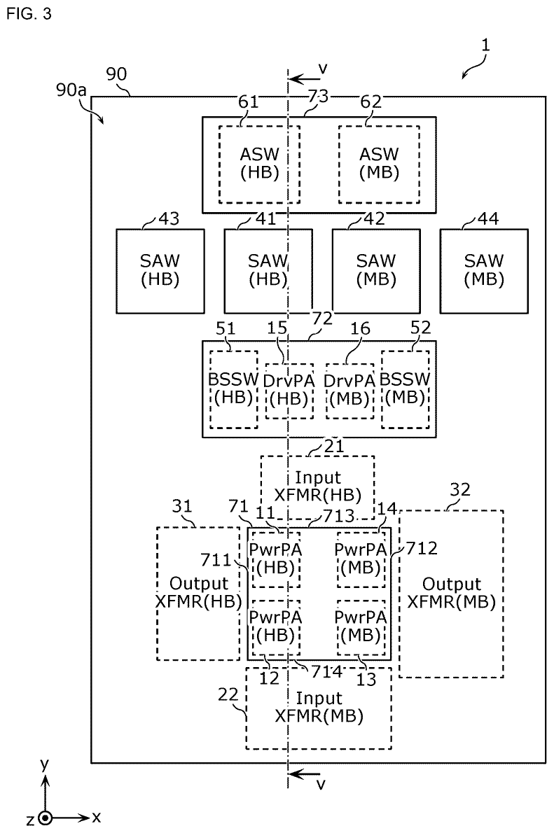

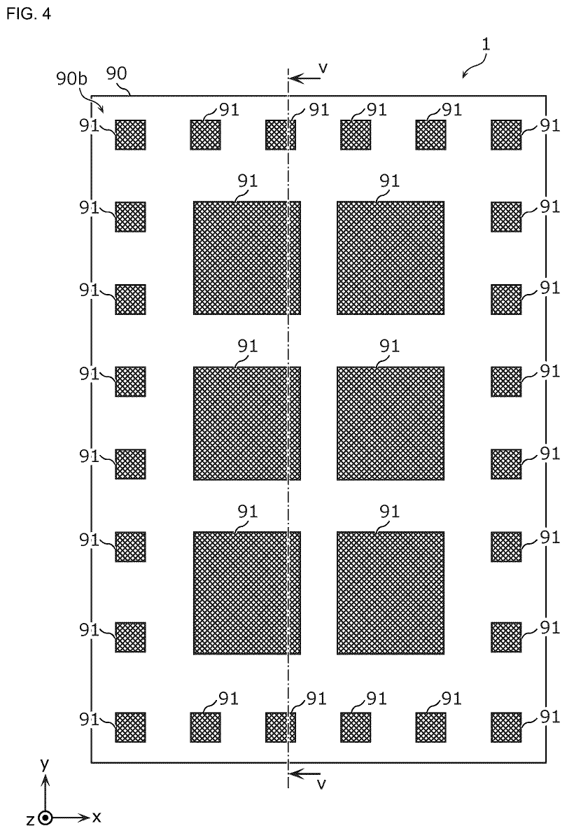

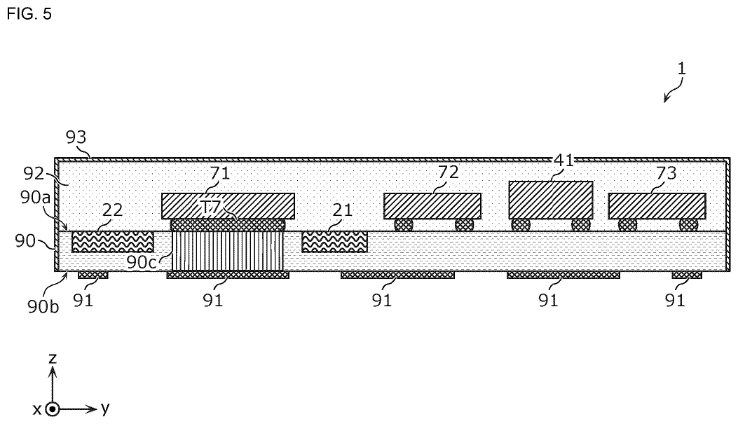

Next, an implementation example of the radio-frequency module 1 having the above circuit configuration is described with reference to FIGS. 3, 4, and 5. FIG. 3 is a plan view of the radio-frequency module 1 according to the present embodiment. FIG. 4 is a plan view of the radio-frequency module 1 according to the present embodiment, seen through to show a main surface 90b of a module laminate 90 from the positive side of the z-axis. FIG. 5 is a sectional view of the radio-frequency module 1 according to the present embodiment. The cross section of the radio-frequency module 1 in FIG. 5 is taken along line v-v in FIGS. 3 and 4.

To make it easier to understand the placement relation between the components, FIG. 3 a resin member covering a plurality of circuit components and a metal shield covering the resin member are omitted for clarity.

Note that FIGS. 3 to 5 represent example configurations, and the radio-frequency module 1 may be implemented using any of various circuit implementations and circuit technologies. Thus, the description of the radio-frequency module 1 provided below is not to be construed as limiting.

The radio-frequency module 1 includes semiconductor integrated components 71, 72, and 73, the module laminate 90, a plurality of external connection terminals 91, a resin member 92, and a metal shield 93.

The module laminate 90 has main surfaces 90a and 90b facing each other. The main surface 90a is an example of the first main surface, and the main surface 90b is an example of the second main surface. A via conductor 90c is formed in the module laminate 90, penetrating through the module laminate 90. Interconnections, via conductors, and the like that are also formed in the module laminate 90 and on the module laminate 90.

Examples of a substrate that can be used as the module laminate 90 include, but are not limited to, a low-temperature co-fired ceramics (LTCC) or high-temperature co-fired ceramics (HTCC) substrate having a laminated structure of a plurality of dielectric layers, a component-embedded substrate, a substrate with a redistribution layer (RDL), and a printed substrate.

The semiconductor integrated component 71 is an example of the first semiconductor integrated component and includes the power amplifiers 11 and 12 (PwrPA(HB)) and the power amplifiers 13 and 14 (PwrPA(MB)). The semiconductor integrated component 71 is disposed on the main surface 90a of the module laminate 90 and is rectangular in plan view of the module laminate 90. Specifically, the semiconductor integrated component 71 has four sides 711, 712, 713, and 714. The sides 711 and 712 are an example of the first side and an example of the second side, respectively, and face each other in plan view of the module laminate 90. The sides 713 and 714 are an example of the third side and an example of the fourth side, respectively, and face each other in plan view of the module laminate 90, and are adjacent to the sides 711 and 712.

As a semiconductor material for the semiconductor integrated component 71, silicon-germanium (SiGe) or gallium arsenide (GaAs) may be used. In this case, the power amplifiers 11 to 14 can be formed of heterojunction bipolar transistors (HBTs). Note that as a semiconductor material for the semiconductor integrated component 71, gallium nitride (GaN) or silicon carbide (SiC) can also be used. In this case, the power amplifiers 11 to 14 can be formed of high-electron-mobility transistors (HEMTs) or metal-semiconductor field-effect transistors (MESFETs). Note that as a semiconductor material for the semiconductor integrated component 71, single-crystal silicon (Si) can also be used. In this case, the power amplifiers 11 to 14 may be formed of complementary metal-oxide-semiconductor (CMOS) and may be manufactured using the Silicon-On-Insulator (SOI) process.

The semiconductor integrated component 72 is an example of the second semiconductor integrated component and includes the power amplifier 15 (DrvPA(HB)), the power amplifier 16 (DrvPA(MB)), the switch 51 (BSSW(HB)), and the switch 52 (BSSW(MB)). The semiconductor integrated component 72 is disposed on the main surface 90a of the module laminate 90.

As a semiconductor material for the semiconductor integrated component 72, a semiconductor material different from the semiconductor integrated component 71 can be used. Examples of a semiconductor material usable for the semiconductor integrated component 72 include single-crystal silicon (Si), gallium nitride (GaN), and silicon carbide (SiC). In this case, the power amplifiers 15 and 16 can be formed of field effect transistors (FETs) or specifically SOI-CMOS. Note that a semiconductor material for the semiconductor integrated component 72 is not limited to single-crystal silicon (Si), gallium nitride (GaN), and silicon carbide (SiC). Also, an amplification transistor for the power amplifiers 15 and 16 is not limited to a FET.

The semiconductor integrated component 73 includes the switches 61 and 62 and is disposed on the main surface 90a of the module laminate 90. As a semiconductor material for the semiconductor integrated component 73, the same material as that for the semiconductor integrated component 72 can be used.

The splitter 21 (InputXFMR(HB)) is formed by interconnection across a plurality of layers of the module laminate 90. For example, the primary coil 214 is formed at at least one of the plurality of layers, and the secondary coil 215 is formed at at least one of the other layers. In this case, the region of the splitter 21 is defined by a portion where the primary coil 214 and the secondary coil 215 overlap each other in plan view of the module laminate 90. The splitter 21 is disposed along the side 713 in plan view of the module laminate 90 and is disposed between the semiconductor integrated components 71 and 72, e.g., in the module laminate in a region adjacent to and facing the third side 713. Also, the splitter 21 is disposed adjacent to the side 713 in plan view of the module laminate 90. Note that the splitter 21 may be a surface-mount device (SMD).

The combiner 31 (OutputXFMR(HB)) is formed by interconnection across a plurality of layers of the module laminate 90. For example, the primary coil 314 is formed at at least one of the plurality of layers, and the secondary coil 315 is formed at at least one of the other layers. In this case, the region of the combiner 31 is defined by a portion where the primary coil 314 and the secondary coil 315 overlap each other in plan view of the module laminate 90. The combiner 31 is disposed along the side 711 in plan view of the module laminate 90, e.g., disposed on the module laminate in a region adjacent to and facing the first side. Also, the combiner 31 is disposed adjacent to the side 711 in plan view of the module laminate 90. Note that the combiner 31 may be an SMD. The first splitter 21 and the first combiner 31 are arranged such that a signal path from the first input terminal to the third output terminal forms a substantially orthogonal (L-shaped) turn, thereby minimizing the trace length between the first semiconductor integrated component 71 and the output stage, reducing parasitic inductance and phase imbalance in the high-frequency range.

The splitter 22 (InputXFMR(MB)) is formed by interconnection across the plurality of layers of the module laminate 90. For example, the primary coil 224 is formed at at least one of the plurality of layers, and the secondary coil 225 is formed at at least one of the other layers. In this case, the region of the splitter 22 is defined by a portion where the primary coil 224 and the secondary coil 225 overlap each other in plan view of the module laminate 90. The splitter 22 is disposed along the side 714 in plan view of the module laminate 90. Also, the splitter 22 is disposed adjacent to the side 714 in plan view of the module laminate 90. Note that the splitter 22 may be an SMD.

The combiner 32 (OutputXFMR(MB)) is formed by interconnection across a plurality of layers of the module laminate 90. For example, the primary coil 324 is formed at at least one of the plurality of layers, and the secondary coil 325 is formed at at least one of the other layers. In this case, the region of the combiner 32 is defined by a portion where the primary coil 324 and the secondary coil 325 overlap each other in plan view of the module laminate 90. The combiner 32 is disposed along the side 712 in plan view of the module laminate 90. Also, the combiner 32 is disposed adjacent to the side 712 in plan view of the module laminate 90. Note that the combiner 32 may be an SMD.

The filters 41 and 43 (SAW(HB)) as well as the filters 42 and 44 (SAW(MB)) are surface acoustic wave (SAW) filters and are disposed on the main surface 90a of the module laminate 90. Note that the filters 41 to 44 are not limited to SAW filters. For example, some or all of the filters 41 to 44 may be bulk acoustic wave (BAW) filters, LC or dielectric filters, or a combination of these.

The plurality of external connection terminals 91 are disposed on the main surface 90b of the module laminate 90 and include the antenna connection terminals 101 and 102, the radio-frequency input terminals 111 and 112, and a ground terminal. Some or all of the plurality of external connection terminals 91 are, outside the radio-frequency module 1, electrically connected to input/output terminals and/or a ground terminal on a motherboard disposed at a location in the negative direction of the z-axis of the radio-frequency module 1. Also, some or all of the plurality of external connection terminals 91 are, inside the radio-frequency module 1, electrically connected to components in the module laminate 90 and on the module laminate 90.

The resin member 92 covers at least part of the components on the main surface 90a of the module laminate 90. For example, a material usable for the resin member 92 may be, but not limited to, epoxy resin. The resin member 92 has a function to ensure the reliability of the components on the main surface 90a, such as mechanical strength and moisture resistance.

The metal shield 93 is a metal thin film formed on the surface of the resin member 92 by, for example, sputtering. The metal shield 93 is formed to cover at least part of the surface of the resin member 92 (the top and side surfaces). The metal shield 93 is connected to the ground and can inhibit external noise from intruding into an electronic component constituting the radio-frequency module 1 and noise generated in the radio-frequency module 1 from interfering with another module or another device.

### [1.4. Layout of Semiconductor Integrated Component 71]

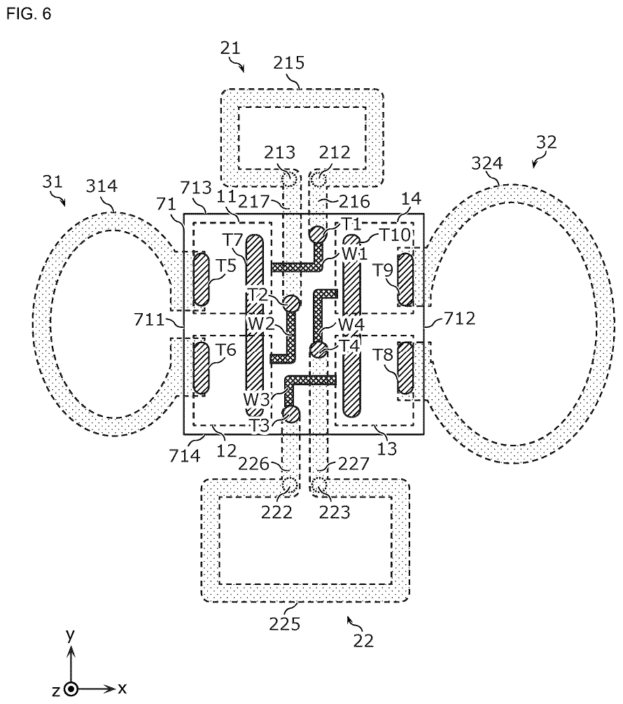

Next, the layout around the semiconductor integrated component 71 is described with reference to FIG. 6. FIG. 6 is a layout diagram of the semiconductor integrated component 71, the splitters 21 and 22, and the combiners 31 and 32 according to the present embodiment.

Note that FIG. 6 shows an example layout, and the semiconductor integrated component 71 may be implemented using any of various circuit implementations and circuit technologies. Thus, the description of the semiconductor integrated component 71 provided below is not to be construed as limiting.

The semiconductor integrated component 71 includes, in addition to the power amplifiers 11 to 14, component terminals T1, T2, T3, T4, T5, T6, T7, T8, T9, and T10 and interconnections W1, W2, W3, and W4.

The power amplifiers 11 and 12 are disposed along the side 711 inside the semiconductor integrated component 71, e.g., disposed within the peripheral boundary of the first side 711. The power amplifiers 11 and 12 are disposed with their output ends closer to the side 711 than their input ends are. Conversely, the power amplifiers 11 and 12 are disposed with their input ends closer to the center of the semiconductor integrated component 71 than their output ends are. Also, the power amplifier 11 is disposed closer to the side 713 than the power amplifier 12. Thus, the power amplifiers 11 and 12 are disposed along the side 711 side by side in this order in the direction from the side 713 to the side 714.

The power amplifiers 13 and 14 are disposed along the side 712 inside the semiconductor integrated component 71. The power amplifiers 13 and 14 are disposed with their output ends closer to the side 712 than their input ends are. Conversely, the power amplifiers 13 and 14 are disposed with their input ends closer to the center of the semiconductor integrated component 71 than their output ends are. Also, the power amplifier 13 is disposed closer to the side 714 than the power amplifier 14. In other words, the power amplifiers 13 and 14 are disposed along the side 712 side by side in this order in the direction from the side 714 to the side 713.

The component terminal T1 is an example of the first component terminal and is disposed on the main surface of the semiconductor integrated component 71 that faces the module laminate 90. The component terminal T1 is connected to the output terminal 212 of the splitter 21 outside the semiconductor integrated component 71 through an interconnection 216. Also, the component terminal T1 is connected to the input end of the power amplifier 11 (e.g., the base electrode of an HBT) inside the semiconductor integrated component 71 through the interconnection W1.

The component terminal T2 is an example of the second component terminal and is disposed on the main surface of the semiconductor integrated component 71 that faces the module laminate 90. The component terminal T2 is connected to the output terminal 213 of the splitter 21 outside the semiconductor integrated component 71 through an interconnection 217. Also, the component terminal T2 is connected to the input end of the power amplifier 12 (e.g., the base electrode of an HBT) inside the semiconductor integrated component 71 through the interconnection W2.

The component terminal T3 is an example of the third component terminal and is disposed on the main surface of the semiconductor integrated component 71 that faces the module laminate 90. The component terminal T3 is connected to the output terminal 222 of the splitter 22 outside the semiconductor integrated component 71 through an interconnection 226. Also, the component terminal T3 is connected to the input end of the power amplifier 13 (e.g., the base electrode of an HBT) inside the semiconductor integrated component 71 through the interconnection W3.

The component terminal T4 is an example of the fourth component terminal and is disposed on the main surface of the semiconductor integrated component 71 that faces the module laminate 90. The component terminal T4 is connected to the output terminal 223 of the splitter 22 outside the semiconductor integrated component 71 through an interconnection 227. Also, the component terminal T4 is connected to the input end of the power amplifier 14 (e.g., the base electrode of an HBT) inside the semiconductor integrated component 71 through the interconnection W4.

The component terminal T5 is disposed on the main surface of the semiconductor integrated component 71 that faces the module laminate 90. The component terminal T5 is connected to the input terminal 311 of the combiner 31 outside the semiconductor integrated component 71. Also, the component terminal T5 is connected to the output end of the power amplifier 11 (e.g., the collector electrode of an HBT) inside the semiconductor integrated component 71.

The component terminal T6 is disposed on the main surface of the semiconductor integrated component 71 that faces the module laminate 90. The component terminal T6 is connected to the input terminal 312 of the combiner 31 outside the semiconductor integrated component 71. Also, the component terminal T6 is connected to the output end of the power amplifier 12 (e.g., the collector electrode of an HBT) inside the semiconductor integrated component 71.

The component terminal T7 is disposed on the main surface of the semiconductor integrated component 71 that faces the module laminate 90. The component terminal T7 is connected to the external connection terminals 91 (a ground terminal) outside the semiconductor integrated component 71 through the via conductor 90c of the module laminate 90. Also, the component terminal T7 is connected to the ground ends of the power amplifiers 11 and 12 (e.g., the emitter electrodes of HBTs) inside the semiconductor integrated component 71.

The component terminal T8 is disposed on the main surface of the semiconductor integrated component 71 that faces the module laminate 90. The component terminal T8 is connected to the input terminal 321 of the combiner 32 outside the semiconductor integrated component 71. Also, the component terminal T8 is connected to the output end of the power amplifier 13 (e.g., the collector electrode of an HBT) inside the semiconductor integrated component 71.

The component terminal T9 is disposed on the main surface of the semiconductor integrated component 71 that faces the module laminate 90. The component terminal T9 is connected to the input terminal 322 of the combiner 32 outside the semiconductor integrated component 71. Also, the component terminal T9 is connected to the output end of the power amplifier 14 (e.g., the collector electrode of an HBT) inside the semiconductor integrated component 71.

The component terminal T10 is disposed on the main surface of the semiconductor integrated component 71 that faces the module laminate 90. The component terminal T10 is connected to the external connection terminals 91 (the ground terminal) outside the semiconductor integrated component 71 through a via conductor in the module laminate 90. Also, the component terminal T10 is connected to the ground ends of the power amplifiers 13 and 14 (e.g., the emitter electrodes of HBTs) inside the semiconductor integrated component 71.

The interconnection W1 is an example of the first interconnection and is disposed inside the semiconductor integrated component 71. The interconnection W1 electrically connects the component terminal T1 to the input end of the power amplifier 11. The interconnection W1 overlaps with none of the interconnections W2, W3, and W4 in plan view of the module laminate 90.

The interconnection W2 is an example of the second interconnection and is disposed inside the semiconductor integrated component 71. The interconnection W2 electrically connects the component terminal T2 to the input end of the power amplifier 12. The interconnection W2 overlaps with none of the interconnections W1, W3, and W4 in plan view of the module laminate 90.

The interconnection W3 is an example of the third interconnection and is disposed inside the semiconductor integrated component 71. The interconnection W3 electrically connects the component terminal T3 to the input end of the power amplifier 13. The interconnection W3 overlaps with none of the interconnections W1, W2, and W4 in plan view of the module laminate 90.

The interconnection W4 is an example of the fourth interconnection and is disposed inside the semiconductor integrated component 71. The interconnection W4 electrically connects the component terminal T4 to the input end of the power amplifier 14. The interconnection W4 overlaps with none of the interconnections W1, W2, and W3 in plan view of the module laminate 90.

The interconnections 216, 217, 226, and 227 are disposed on the main surface 90a of the module laminate 90 and/or in the module laminate 90. The interconnection 216 electrically connects the output terminal 212 of the splitter 21 to the component terminal T1 of the semiconductor integrated component 71. The interconnection 217 electrically connects the output terminal 213 of the splitter 21 to the component terminal T2 of the semiconductor integrated component 71. The interconnection 226 electrically connects the output terminal 222 of the splitter 22 to the component terminal T3 of the semiconductor integrated component 71. The interconnection 227 electrically connects the output terminal 223 of the splitter 22 to the component terminal T4 of the semiconductor integrated component 71.

Note that some or all of the interconnections 216, 217, 226, and 227 may be bonding wires. In this case, the component terminals T1 to T4 may be disposed on the main surface of the semiconductor integrated component 71 on the opposite side from the module laminate 90.

### [1.5. Overview]

As thus described, the radio-frequency module 1 according to the present embodiment has the module laminate 90, the semiconductor integrated component 71 disposed at the module laminate 90 and including the power amplifiers 11 and 12, the splitter 21 disposed at the module laminate 90 and including the input terminal 211, the output terminal 212 connected to the input end of the power amplifier 11, and the output terminal 213 connected to the input end of the power amplifier 12, and the combiner 31 disposed at the module laminate 90 and including the input terminal 311 connected to the output end of the power amplifier 11, the input terminal 312 connected to the output end of the power amplifier 12, and the output terminal 313. The splitter 21 and the combiner 31 are each a transformer or a quadrature hybrid circuit. In plan view of the module laminate 90, the semiconductor integrated component 71 has the sides 711 and 712 facing each other and the sides 713 and 714 adjacent to the sides 711 and 712 and facing each other. The power amplifiers 11 and 12 are disposed along the side 711 inside the semiconductor integrated component 71. The splitter 21 is disposed along the side 713 outside the semiconductor integrated component 71 in plan view of the module laminate 90. The combiner 31 is disposed along the side 711 outside the semiconductor integrated component 71 in plan view of the module laminate 90.

According to this, the splitter 21 and the combiner 31 are disposed respectively along the mutually adjacent sides 711 and 713 of the semiconductor integrated component 71 including the power amplifiers 11 and 12. This can reduce an increase in the length of interconnection from the splitter 21 to the combiner 31 with the two power amplifiers 11 and 12 in between. Especially when the distance between the sides 711 and 712 facing each other is long, the length of interconnection can be shortened more effectively than in a case where the splitter 21 and the combiner 31 are disposed along the sides 711 and 712, respectively, outside the semiconductor integrated component 71. Further, isolation between the splitter 21 and the combiner 31 can be improved compared to a case where the splitter 21 and the combiner 31 is disposed along the same side of the semiconductor integrated component 71. Also, a difference between the length of interconnection from the splitter 21 to the power amplifier 11 and the length of interconnection from the splitter 21 to the power amplifier 12 can be reduced, which can improve the characteristics of the power amplifiers 11 and 12.

Also, for example, in the radio-frequency module 1 of the present embodiment, the semiconductor integrated component 71 may include the component terminal T1 connected to the output terminal 212 of the splitter 21 and the component terminal T2 connected to the output terminal 213 of the splitter 21. The component terminal T1 may be connected to the input end of the power amplifier 11 inside the semiconductor integrated component 71, and the component terminal T2 may be connected to the input end of the power amplifier 12 inside the semiconductor integrated component 71. The power amplifier 11 may be disposed closer to the side 713 than the power amplifier 12 is, and the component terminal T1 may be disposed closer to the side 713 and farther from the side 711 than the component terminal T2.

According to this, a difference between the length of interconnection from the component terminal T1 to the power amplifier 11 and the length of interconnection from the component terminal T2 to the power amplifier 12 can be reduced, which can improve the characteristics of the power amplifiers 11 and 12.

Also, for example, the radio-frequency module 1 according to the present embodiment may be such that the interconnection W1 connecting the component terminal T1 to the input end of the power amplifier 11 does not overlap with the interconnection W2 connecting the component terminal T2 to the input end of the power amplifier 12 in plan view of the module laminate 90.

According to this, isolation between the power amplifiers 11 and 12 can be improved.

Also, for example, in the radio-frequency module 1 according to the present embodiment, the semiconductor integrated component 71 may further include the power amplifiers 13 and 14, and the radio-frequency module 1 may further have the splitter 22 disposed at the module laminate 90 and including the input terminal 221, the output terminal 222 connected to the input end of the power amplifier 13, and the output terminal 223 connected to the input end of the power amplifier 14 and the combiner 32 disposed at the module laminate 90 and including the input terminal 321 connected to the output end of the power amplifier 13, the input terminal 322 connected to the output end of the power amplifier 14, and the output terminal 323. The splitter 22 and the combiner 32 may each be a transformer or a quadrature hybrid circuit.

According to this, the semiconductor integrated component 71 includes the power amplifiers 13 and 14 in addition to the power amplifiers 11 and 12; therefore, the number of components can be reduced to achieve size reduction of the radio-frequency module 1.

Also, for example, in the radio-frequency module 1 according to the present embodiment, the power amplifiers 13 and 14 may be disposed along the side 712 inside the semiconductor integrated component 71, and the combiner 32 may be disposed along the side 712 outside the semiconductor integrated component 71 in plan view of the module laminate 90.

According to this, the combiners 31 and 32 are disposed along the mutually facing sides 711 and 712 of the semiconductor integrated component 71, respectively. Thus, isolation between the combiners 31 and 32 can be improved. The isolation improvement effect is especially significant because amplified radio-frequency signals are transmitted in the combiners 31 and 32.

Also, for example, in the radio-frequency module 1 according to the present embodiment, the splitter 22 is disposed along the side 714 outside the semiconductor integrated component 71 in plan view of the module laminate 90.

According to this, the splitters 21 and 22 are disposed along the mutually facing sides 713 and 714 of the semiconductor integrated component 71, respectively. Thus, isolation between the splitters 21 and 22 can be improved.

Also, for example, in the radio-frequency module 1 according to the present embodiment, the semiconductor integrated component 71 may include the component terminal T3 connected to the output terminal 222 of the splitter 22 and the component terminal T4 connected to the output terminal 223 of the splitter 22. The component terminal T3 may be connected to the input end of the power amplifier 13 inside the semiconductor integrated component 71, and the component terminal T4 may be connected to the input end of the power amplifier 14 inside the semiconductor integrated component 71. The power amplifier 13 may be disposed closer to the side 714 than the power amplifier 14 is, and the component terminal T3 may be disposed closer to the side 714 and farther from the side 712 than the component terminal T4.

According to this, a difference between the length of interconnection from the component terminal T3 to the power amplifier 13 and the length of interconnection from the component terminal T4 to the power amplifier 14 can be reduced, which can improve the characteristics of the power amplifiers 13 and 14.

Also, for example, the radio-frequency module 1 according to the present embodiment may be such that the interconnection W3 connecting the component terminal T3 to the input end of the power amplifier 13 in plan view of the module laminate 90 does not overlap with the interconnection W4 connecting the component terminal T4 to the input end of the power amplifier 14.

According to this, isolation between the power amplifiers 13 and 14 can be improved.

Also, for example, the radio-frequency module 1 according to the present embodiment may be such that the interconnection W1, the interconnection W2, the interconnection W3, and the interconnection W4 do not overlap with one another in plan view of the module laminate 90.

According to this, isolation between the power amplifiers 11 to 14 can be improved.

Also, for example, in the radio-frequency module 1 according to the present embodiment, the module laminate 90 may have the main surface 90a and the main surface 90b facing each other, and the semiconductor integrated component 71 may be disposed at the main surface 90a. The radio-frequency module 1 may further have the semiconductor integrated component 72 disposed at the main surface 90a and the plurality of external connection terminals 91 disposed at the main surface 90b, the semiconductor integrated component 72 including the power amplifier 15 having an output end connected to the input terminal 211 of the splitter 21 and the power amplifier 16 having an output end connected to the input terminal 221 of the splitter 22. The output terminal 313 of the combiner 31 may be connected to the filter 41 having a pass band including a transmission band of Band A, and the output terminal 323 of the combiner 32 may be connected to the filter 42 having a pass band including a transmission band of Band B lower than the transmission band of Band A. In plan view of the module laminate 90, the splitter 21 may be disposed between the semiconductor integrated components 71 and 72.

According to this, the splitter 21 is disposed between the semiconductor integrated components 71 and 72; therefore, the length of interconnection from the power amplifier 15 included in the semiconductor integrated component 72 to the power amplifiers 11 and 12 included in the semiconductor integrated component 71 with the splitter 21 in between can be shortened. Because Band A is higher than Band B, the effect of shortening the length of interconnection for signals in Band A is especially significant.

Also, for example, in the radio-frequency module 1 according to the present embodiment, the semiconductor integrated component 72 may further include the switch 51 connected between the combiner 31 and the filter 41 and the switch 52 connected between the combiner 32 and the filter 42.

According to this, the switches 51 and 52 are included in the semiconductor integrated component 72 along with the power amplifiers 15 and 16; therefore, the number of components can be reduced to reduce the size of the radio-frequency module 1.

### Modification of Embodiment 1

Next, a modification of Embodiment 1 is described. The present modification differs from Embodiment 1 described above mainly in that the radio-frequency module is implemented on both surfaces of the module laminate. The following describes the present modification with reference to the drawings, focusing mainly on differences from Embodiment 1 described above.

Note that the communication device 5 according to the present modification is the same as the communication device 5 according to Embodiment 1 described above except for having a radio-frequency module 1A in place of the radio-frequency module 1. Thus, a diagram and a description of the configuration of the communication device 5 according to the present modification are omitted.

Also, the radio-frequency module 1A according to the present modification has the same circuit configuration as the radio-frequency module 1 according to Embodiment 1 described above. Thus, a diagram and a description of the circuit configuration of the radio-frequency module 1A according to the present modification are omitted.

### [1.6. Implementation Example of Radio-Frequency Module 1A]

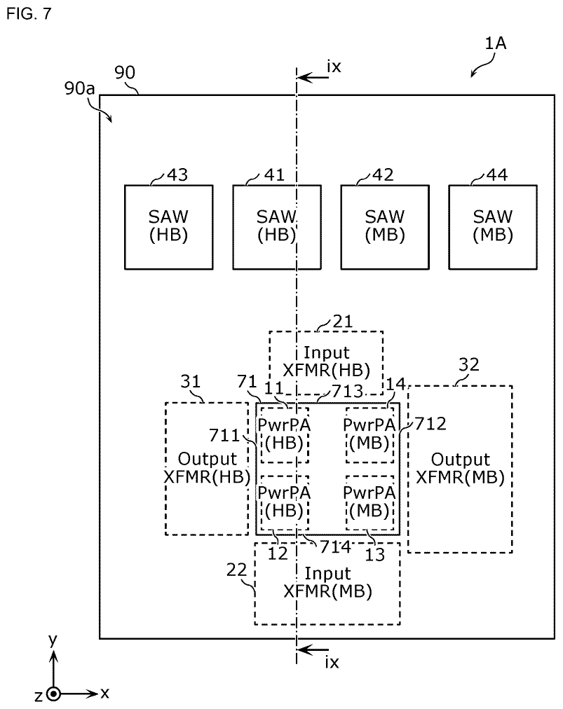

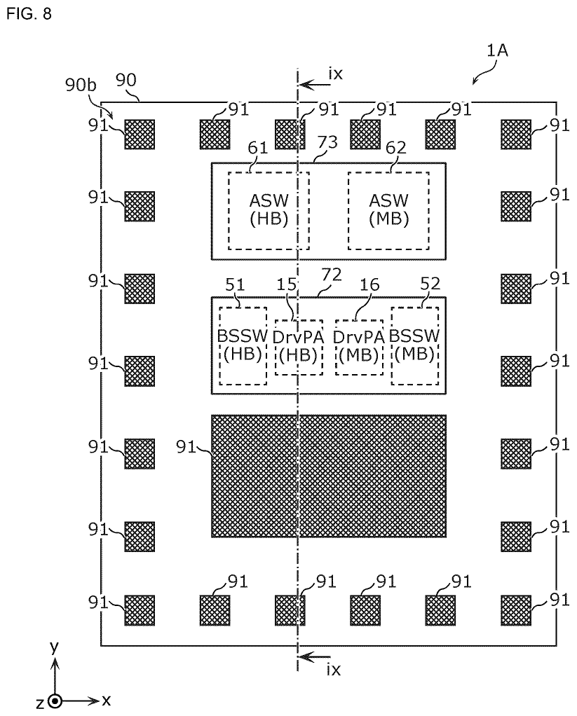

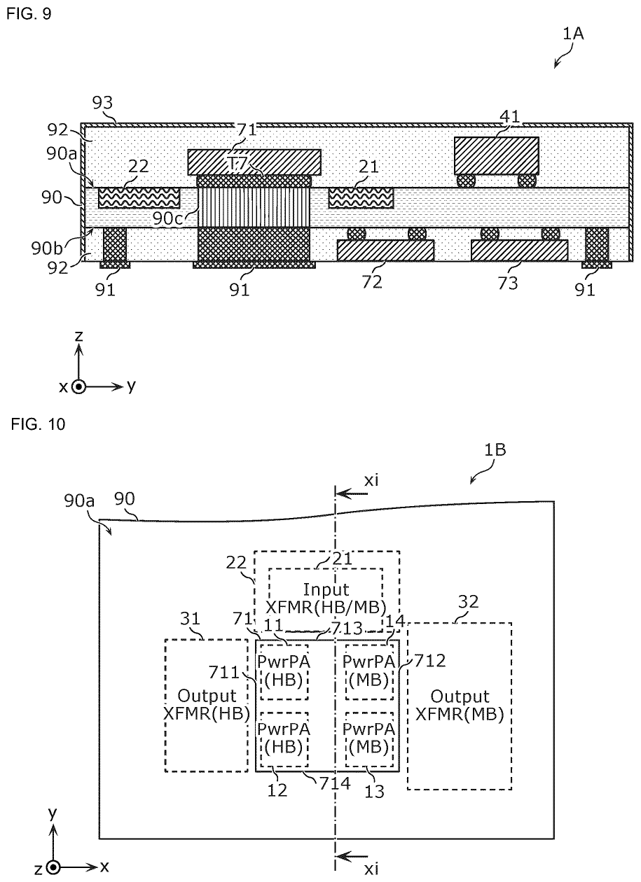

An implementation example of the radio-frequency module 1A is described with reference to FIGS. 7, 8, and 9. FIG. 7 is a plan view of the radio-frequency module 1A according to the present modification. FIG. 8 is a plan view of the radio-frequency module 1A according to the present modification, seen through to show the main surface 90b of the module laminate 90 from the positive side of the z-axis. FIG. 9 is a sectional view of the radio-frequency module 1A according to the present modification. The cross section of the radio-frequency module 1A in FIG. 9 is taken along line ix-ix in FIGS. 7 and 8.

In the present modification, the semiconductor integrated components 72 and 73 are disposed on the main surface 90b of the module laminate 90. In plan view of the module laminate 90, the semiconductor integrated component 72 is closer to the side 713 of the semiconductor integrated component 71 than to the side 714 thereof.

### [1.7. Overview]

As thus described, in the radio-frequency module 1A according to the present modification, the module laminate 90 may have the main surfaces 90a and 90b facing each other. The semiconductor integrated component 71 may be disposed at the main surface 90a, and the radio-frequency module 1A may further have the semiconductor integrated component 72 disposed at the main surface 90b and the plurality of external connection terminals 91 disposed at the main surface 90b, the semiconductor integrated component 72 including the power amplifier 15 having an output end connected to the input terminal 211 of the splitter 21 and the power amplifier 16 having an output end connected to the input terminal 221 of the splitter 22. The output terminal 313 of the combiner 31 may be connected to the filter 41 having a pass band including a transmission band of Band A, and the output terminal 323 of the combiner 32 may be connected to the filter 42 having a pass band including a transmission band of Band B lower than the transmission band of Band A. In plan view of the module laminate 90, the semiconductor integrated component 72 may be closer to the side 713 of the semiconductor integrated component 71 than to the side 714 thereof.

According to this, because the semiconductor integrated components 71 and 72 are disposed at the different main surfaces 90a and 90b of the module laminate 90, the radio-frequency module 1A can be reduced in size. Also, because the semiconductor integrated component 72 is closer to the side 713 of the semiconductor integrated component 71 than to the side 714 thereof, the length of interconnection from the power amplifier 15 included in the semiconductor integrated component 72 to the power amplifiers 11 and 12 included in the semiconductor integrated component 71 with the splitter 21 in between can be shortened. Because Band A is higher than Band B, the effect of shortening the length of interconnection for signals in Band A is especially significant.

### Embodiment 2

Next, Embodiment 2 is described. The present embodiment differs from Embodiment 1 described above mainly in the placement of the splitter 22. The following describes the present embodiment with reference to the drawings, focusing mainly on differences from Embodiment 1described above.

Note that the communication device 5 according to the present embodiment is the same as the communication device 5 according to Embodiment 1 described above except for having a radio-frequency module 1B in place of the radio-frequency module 1. Thus, a diagram and a description of the configuration of the communication device 5 according to the present embodiment are omitted.

Also, the radio-frequency module 1B according to the present embodiment has the same circuit configuration as the radio-frequency module 1 according to Embodiment 1 described above. Thus, a diagram and a description of the circuit configuration of the radio-frequency module 1B according to the present embodiment are omitted.

### [2.1. Implementation Example of Radio-Frequency Module 1B]

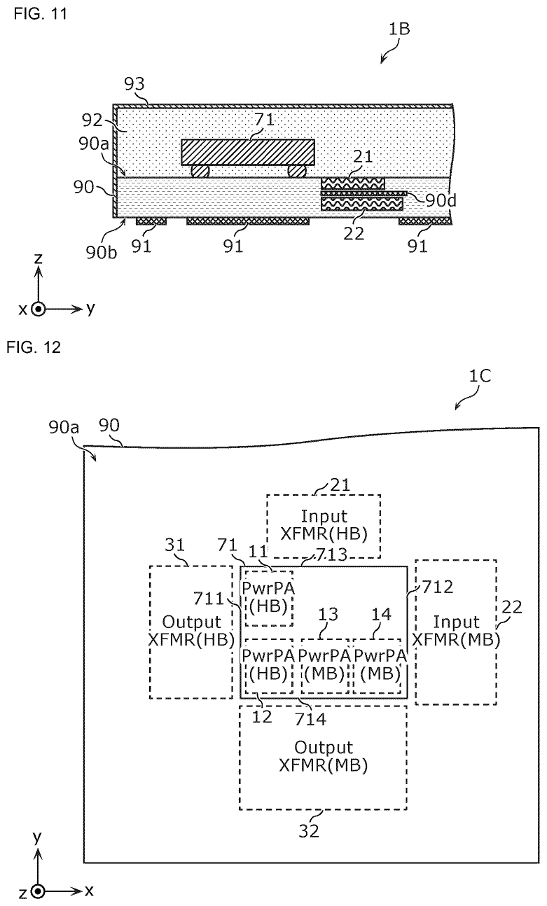

An implementation example of the radio-frequency module 1B is described with reference to FIGS. 10 and 11. FIG. 10 is a partial plan view of the radio-frequency module 1B according to the present embodiment. FIG. 11 is a sectional view of the radio-frequency module 1B according to the present embodiment. The cross section of the radio-frequency module 1B in FIG. 11 is taken along line xi-xi in FIG. 10.

In the present embodiment, the splitter 22 is disposed along the side 713 outside the semiconductor integrated component 71 in plan view of the module laminate 90. Also, the splitter 22 is disposed adjacent to the side 713 in plan view of the module laminate 90. The splitter 22 overlaps with the splitter 21 at least partially in plan view of the module laminate 90 and is formed by interconnection on a layer of the module laminate 90 different from the layer for the splitter 21. As shown in FIG. 11, the splitter 21 is disposed closer to the main surface 90a than the splitter 22. A ground electrode 90d may be disposed between the splitters 21 and 22. Then, isolation between the splitters 21 and 22 can be improved.

Note that the placement of the splitters 21 and 22 is not limited to the placement in FIGS. 10 and 11. For example, the splitter 22 may be disposed closer to the main surface 90a than the splitter 21. Also, in plan view of the module laminate 90, the splitter 22 may not overlap the splitter 21, and for example, the splitters 21 and 22 may be disposed side by side along the side 713.

### 2.2. Overview

As thus described above, in the radio-frequency module 1B according to the present embodiment, the splitter 22 may be disposed along the side 713 outside the semiconductor integrated component 71 in plan view of the module laminate 90.

According to this, because the splitter 22 is disposed along the side 713, the length of interconnection from the power amplifier 16 included in the semiconductor integrated component 72 to the power amplifiers 13 and 14 included in the semiconductor integrated component 71 with the splitter 22 in between can be shortened.

### Embodiment 3

Next, Embodiment 3 is described. The present embodiment differs from Embodiment 1 described above mainly in that the positions of the splitter 22 and the combiner 32 are interchanged. The following describes the present embodiment with reference to the drawings, focusing mainly on differences from Embodiment 1 described above.

Note that the communication device 5 according to the present embodiment is the same as the communication device 5 according to Embodiment 1 described above except for having a radio-frequency module 1C in place of the radio-frequency module 1. Thus, a diagram and a description of the configuration of the communication device 5 according to the present embodiment are omitted.

Also, the radio-frequency module 1C according to the present embodiment has the same circuit configuration as the radio-frequency module 1 according to Embodiment 1 described above. Thus, a diagram and a description of the circuit configuration of the radio-frequency module 1C according to the present embodiment are omitted.

### [3.1. Implementation Example of Radio-Frequency Module 1C]

An implementation example of the radio-frequency module 1C is described with reference to FIG. 12. FIG. 12 is a partial plan view of the radio-frequency module 1C according to the present embodiment.

In the present embodiment, the power amplifiers 13 and 14 are disposed along the side 714 inside the semiconductor integrated component 71. The combiner 32 is disposed along the side 714 outside the semiconductor integrated component 71 in plan view of the module laminate 90. The splitter 22 is disposed along the side 712 outside the semiconductor integrated component 71 in plan view of the module laminate 90.

### [3.2. Overview]

As thus described in the radio-frequency module 1C according to the present embodiment, the power amplifiers 13 and 14 may be disposed along the side 714 inside the semiconductor integrated component 71, and the combiner 32 may be disposed along the side 714 outside the semiconductor integrated component 71 in plan view of the module laminate 90.

According to this, because the semiconductor integrated component 71 includes the power amplifiers 13 and 14 in addition to the power amplifiers 11 and 12, the number of components can be reduced, and the radio-frequency module 1C can therefore be reduced in size.

Also, for example, in the radio-frequency module 1C according to the present embodiment, the splitter 22 may be disposed along the side 712 outside the semiconductor integrated component 71 in plan view of the module laminate 90.

According to this, the combiner 31 and the splitter 22 are disposed along the mutually facing sides 711 and 712 of the semiconductor integrated component 71, respectively. Thus, isolation between the combiner 31 and the splitter 22 can be improved.

### Embodiment 4

Next, Embodiment 4 is described. The present embodiment corresponds to a combination of Embodiments 2 and 3. The present embodiment differs from Embodiment 2described above mainly in the placement of the combiner 32 and differs from Embodiment 3 described above mainly in the placement of the splitter 22. The following describes the present embodiment with reference to the drawings, focusing mainly on differences from Embodiments 2 and 3 described above.

Note that the communication device 5 according to the present embodiment is the same as the communication device 5 according to Embodiment 1 described above except for having a radio-frequency module 1D in place of the radio-frequency module 1. Thus, a diagram and a description of the configuration of the communication device 5 according to the present embodiment are omitted.

Also, the radio-frequency module 1D according to the present embodiment has the same circuit configuration as the radio-frequency module 1 according to Embodiment 1 described above. Thus, a diagram and a description of the circuit configuration of the radio-frequency module 1D according to the present embodiment are omitted.

### [4.1. Implementation Example of Radio-Frequency Module 1D]

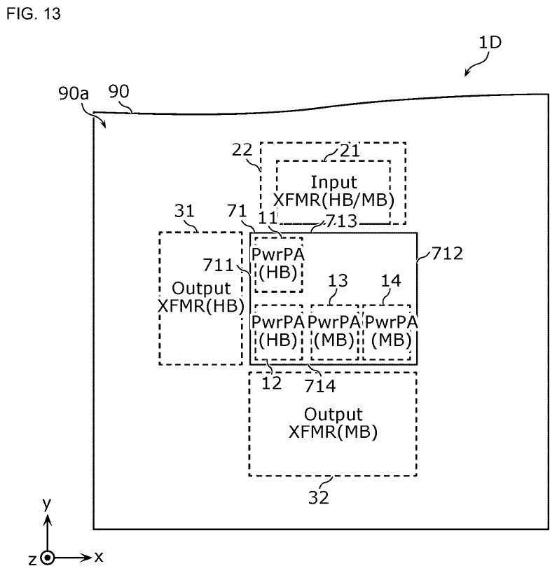

An implementation example of the radio-frequency module 1D is described with reference to FIG. 13. FIG. 13 is a partial plan view of the radio-frequency module 1D according to the present embodiment.

The power amplifiers 13 and 14 are, like in Embodiment 3, disposed along the side 714 inside the semiconductor integrated component 71.

The splitter 22 is, like in Embodiment 2, disposed along the side 713 outside the semiconductor integrated component 71 and adjacent to the side 713 in plan view of the module laminate 90. The splitter 22 overlaps with the splitter 21 at least partially in plan view of the module laminate 90 and is formed by interconnection in a layer in the module laminate 90 different from the layer for the splitter 21.

The combiner 32 is, like in Embodiment 3, disposed along the side 714 outside the semiconductor integrated component 71 and adjacent to the side 714 in plan view of the module laminate 90.

### [4.2. Overview]

As thus described above, in the radio-frequency module 1D according to the present embodiment, the splitter 22 may be disposed along the side 713 outside the semiconductor integrated component 71 in plan view of the module laminate 90.

According to this, because the splitter 22 is disposed along the side 713, the length of interconnection from the power amplifier 16 included in the semiconductor integrated component 72 to the power amplifiers 13 and 14 included in the semiconductor integrated component 71 with the splitter 22 in between can be shortened.

### Other Embodiments

Although the radio-frequency module according to the present disclosure is described above based on the embodiments, the radio-frequency module according to the present disclosure is not limited to the embodiments described above. The present disclosure also includes other embodiments implemented by combining any constituents in the embodiments, modification examples implemented by applying, to any of the embodiments, various modifications with which those skilled in the art come up without departing from the gist of the present disclosure, and various devices equipped with any of the radio-frequency modules described above.

For example, in the circuit configuration of the radio-frequency module according to any of the embodiments described above, another circuit element, interconnection, or the like may be inserted on a path connecting a circuit element and a signal path disclosed in the drawings. For example, a matching circuit may be connected between the combiner 31 and the switch 51 and/or between the combiner 32 and the switch 52. Also, for example, a coupler may be connected between the switch 61 and the antenna connection terminal 101 and/or between the switch 62 and the antenna connection terminal 102.

Also, for example, the modification of Embodiment 1 may be applied to any of the other embodiments. Specifically, the radio-frequency modules according to Embodiments 2 to 4 may be implemented on both sides of the module laminate 90.

Also, for example, the radio-frequency module according to any of the embodiments described above may include a reception circuit in addition to the transmission circuit. In this case, the radio-frequency module may include a reception filter and/or a low-noise amplifier.

The embodiments disclosed herein can be used widely for communication devices such as a mobile phone, as a radio-frequency module disposed at the front end part.

What is claimed is:

1. A radio-frequency module comprising:
a module laminate;
a first semiconductor integrated component disposed at the module laminate, the first semiconductor integrated component having a rectangular shape in plan view defined by a first side and a second side facing each other, and a third side and a fourth side adjacent to the first and second sides and facing each other;
a first power amplifier and a second power amplifier disposed within the first semiconductor integrated component and arranged along the first side;
a first splitter disposed on or in the module laminate at a position adjacent to the third side outside the first semiconductor integrated component, the first splitter including a first input terminal, a first output terminal connected to an input end of the first power amplifier, and a second output terminal connected to an input end of the second power amplifier; and
a first combiner disposed on or in the module laminate at a position adjacent to the first side outside the first semiconductor integrated component, the first combiner including a second input terminal connected to an output end of the first power amplifier, a third input terminal connected to an output end of the second power amplifier, and a third output terminal, wherein
the first splitter and the first combiner each include one of a transformer and a quadrature hybrid circuit.

2. The radio-frequency module according to claim 1, wherein
the first semiconductor integrated component includes a first component terminal connected to the first output terminal of the first splitter and a second component terminal connected to the second output terminal of the first splitter,
inside the first semiconductor integrated component, the first component terminal is connected to the input end of the first power amplifier,
inside the first semiconductor integrated component, the second component terminal is connected to the input end of the second power amplifier,
the first power amplifier is disposed closer to the third side than the second power amplifier is, and
the first component terminal is disposed closer to the third side and farther from the first side than the second component terminal.

3. The radio-frequency module according to claim 2, wherein
in plan view of the module laminate, a first interconnection connecting the first component terminal to the input end of the first power amplifier does not overlap with a second interconnection connecting the second component terminal to the input end of the second power amplifier.

4. The radio-frequency module according to claim 1, wherein
the first semiconductor integrated component further includes a third power amplifier and a fourth power amplifier,
the radio-frequency module further includes:
a second splitter disposed at the module laminate and including a fourth input terminal, a fourth output terminal connected to an input end of the third power amplifier, and a fifth output terminal connected to an input end of the fourth power amplifier and
a second combiner disposed at the module laminate and including a fifth input terminal connected to an output end of the third power amplifier, a sixth input terminal connected to an output end of the fourth power amplifier, and a sixth output terminal, and
the second splitter and the second combiner each include one of a transformer and a quadrature hybrid circuit.

5. The radio-frequency module according to claim 4, wherein
the third power amplifier and the fourth power amplifier are disposed along the second side inside the first semiconductor integrated component, and
the second combiner is disposed along the second side outside the first semiconductor integrated component in plan view of the module laminate.

6. The radio-frequency module according to claim 5, wherein
the second splitter is disposed along the fourth side in plan view of the module laminate.

7. The radio-frequency module according to claim 6, wherein
the first semiconductor integrated component includes a third component terminal connected to the fourth output terminal of the second splitter and a fourth component terminal connected to the fifth output terminal of the second splitter,
inside the first semiconductor integrated component, the third component terminal is connected to the input end of the third power amplifier,
inside the first semiconductor integrated component, the fourth component terminal is connected to the input end of the fourth power amplifier,
the third power amplifier is disposed closer to the fourth side than the fourth power amplifier is, and
the third component terminal is disposed closer to the fourth side and farther from the second side than the fourth component terminal.

8. The radio-frequency module according to claim 7, wherein
in plan view of the module laminate, a third interconnection connecting the third component terminal to the input end of the third power amplifier does not overlap with a fourth interconnection connecting the fourth component terminal to the input end of the fourth power amplifier.

9. The radio-frequency module according to claim 8, wherein
the first semiconductor integrated component includes a first component terminal connected to the first output terminal of the first splitter and a second component terminal connected to the second output terminal of the first splitter,
inside the first semiconductor integrated component, the first component terminal is connected to the input end of the first power amplifier,
inside the first semiconductor integrated component, the second component terminal is connected to the input end of the second power amplifier,
the first power amplifier is disposed closer to the third side than the second power amplifier is, and
the first component terminal is disposed closer to the third side and farther from the first side than the second component terminal.

10. The radio-frequency module according to claim 9, wherein
in plan view of the module laminate, a first interconnection connecting the first component terminal to the input end of the first power amplifier does not overlap with a second interconnection connecting the second component terminal to the input end of the second power amplifier.

11. The radio-frequency module according to claim 10, wherein
the first interconnection, the second interconnection, the third interconnection, and the fourth interconnection do not overlap with one another in plan view of the module laminate.

12. The radio-frequency module according to claim 5, wherein
the second splitter is disposed along the third side outside the first semiconductor integrated component in plan view of the module laminate.

13. The radio-frequency module according to claim 4, wherein
the third power amplifier and the fourth power amplifier are disposed along the fourth side inside the first semiconductor integrated component, and
the second combiner is disposed along the fourth side outside the first semiconductor integrated component in plan view of the module laminate.

14. The radio-frequency module according to claim 13, wherein
the second splitter is disposed along the second side outside the first semiconductor integrated component in plan view of the module laminate.

15. The radio-frequency module according to claim 13, wherein
the second splitter is disposed along the third side outside the first semiconductor integrated component in plan view of the module laminate.

16. The radio-frequency module according to claim 4, wherein
the module laminate has a first main surface and a second main surface facing each other,
the first semiconductor integrated component is disposed at the first main surface,
the radio-frequency module further includes:
a second semiconductor integrated component disposed at the first main surface and including a fifth power amplifier having an output end connected to the first input terminal of the first splitter and a sixth power amplifier having an output terminal connected to the fourth input terminal of the second splitter; and
a plurality of external connection terminals disposed at the second main surface,
the third output terminal of the first combiner is connected to a first filter having a pass band including a transmission band of a first band,
the sixth output terminal of the second combiner is connected to a second filter having a pass band including a transmission band of a second band lower than the transmission band of the first band, and
the first splitter is disposed between the first semiconductor integrated component and the second semiconductor integrated component in plan view of the module laminate.

17. The radio-frequency module according to claim 4, wherein
the module laminate has a first main surface and a second main surface facing each other,
the first semiconductor integrated component is disposed at the first main surface,
the radio-frequency module further includes:
a second semiconductor integrated component disposed at the second main surface and including a fifth power amplifier having an output end connected to the first input terminal of the first splitter and a sixth power amplifier having an output terminal connected to the fourth input terminal of the second splitter; and
a plurality of external connection terminals disposed at the second main surface,
the third output terminal of the first combiner is connected to a first filter having a pass band including a transmission band of a first band,
the sixth output terminal of the second combiner is connected to a second filter having a pass band including a transmission band of a second band lower than the transmission band of the first band, and
the second semiconductor integrated component is closer to the third side of the first semiconductor integrated component than to the fourth side of the first semiconductor integrated component in plan view of the module laminate.

18. The radio-frequency module according to claim 17, wherein
the second semiconductor integrated component further includes
a first switch connected between the first combiner and the first filter and
a second switch connected between the second combiner and the second filter.

19. A communication device comprising:
the radio-frequency module of claim 1;
an antenna connected to the third output terminal; and
a radio-frequency integrated circuit (RFIC) configured to supply a radio-frequency signal to the first input terminal.

20. A radio-frequency module comprising:
a laminate substrate having a first main surface;
a power amplifier chip mounted on the first main surface, the power amplifier chip having four sides including a first side and a third side that are perpendicular to each other;
a first amplification path and a second amplification path integrated into the power amplifier chip, the first and second amplification paths extending in parallel toward the first side;
an input transformer disposed on the laminate substrate along the third side of the power amplifier chip and configured to provide differential signals to the first and second amplification paths; and
an output transformer disposed on the laminate substrate along the first side of the power amplifier chip and configured to combine amplified signals from the first and second amplification paths.
